(19) United States
(12) Patent Application Publication
(10) Pub. No.: US 2025/0201577 A1
(43) Pub. Date: Jun. 19, 2025

(54) METHOD OF FORMING PATTERNS AND METHOD OF MANUFACTURING INTEGRATED CIRCUIT DEVICE BY USING THE SAME

(71) Applicant: Samsung Electronics Co., Ltd., Suwon-si (KR)

(72) Inventors: Jiyeon YI, Suwon-si (KR); Yeongsup SOHN, Suwon-si (KR); Seongbo SHIM, Suwon-si (KR); Moosong LEE, Suwon-si (KR)

(73) Assignee: Samsung Electronics Co., Ltd., Suwon-si (KR)

(21) Appl. No.: 18/975,273

(22) Filed: Dec. 10, 2024

(30) Foreign Application Priority Data
Dec. 13, 2023 (KR) 10-2023-0181161

(51) Int. Cl. H01L 21/311; G03F 7/00; G03F 7/004; H10B 12/00

(52) U.S. Cl. CPC H01L 21/31144; G03F 7/0035; G03F 7/0042; G03F 7/70025; G03F 7/70033; G03F 7/70575; H10B 12/09

(57) ABSTRACT

A method of forming patterns including forming an etch target layer on a substrate, the substrate including a first area and a second area, forming a hardmask structure on the etch target layer, forming a first photoresist layer on the hardmask structure, forming a first photoresist pattern and a first dummy pattern, forming a hardmask pattern corresponding to the first photoresist pattern and a second dummy pattern corresponding to the first dummy pattern, forming a second photoresist layer on the second dummy pattern and the hardmask pattern, forming a second photoresist pattern covering the second dummy pattern and exposing the hardmask pattern, and forming a resulting pattern from the etch target layer by using the hardmask pattern as an etch mask may be provided.

### CROSS-REFERENCE TO RELATED APPLICATION

This application is based on and claims priority under 35 U.S.C. § 119 to Korean Patent Application No. 10-2023-0181161, filed on Dec. 13, 2023, in the Korean Intellectual Property Office, the disclosure of which is incorporated by reference herein in its entirety.

### BACKGROUND

The inventive concepts relate to methods of forming patterns and methods of manufacturing an integrated circuit device, and more particularly, to methods of forming patterns in a plurality of areas having different pattern densities and methods of manufacturing an integrated circuit device by using the methods of forming patterns.

Recently, with the rapid progress in down-scaling of semiconductor memory devices, feature sizes of semiconductor memory devices are becoming more minute, and line widths of patterns constituting semiconductor memory devices are gradually decreasing. Accordingly, the difficulty in a process of simultaneously forming patterns having various shapes, sizes, and densities, which are required for semiconductor memory devices, is increasing.

### SUMMARY

The inventive concepts provide methods of forming patterns and methods of manufacturing an integrated circuit device, in which a critical dimension (CD) deviation of a pattern may be reduced.

In addition, the technical objectives of the inventive concepts are not limited to those mentioned above, and other objectives will be clearly understood by those skilled in the art from the following descriptions.

According to an aspect of the inventive concepts, a method of forming patterns may include forming an etch target layer on a substrate, the substrate including a first area and a second area, forming a hardmask structure on the etch target layer, forming a first photoresist layer on the hardmask structure, forming a first photoresist pattern and a first dummy pattern by exposing and developing the first photoresist layer, forming a hardmask pattern corresponding to the first photoresist pattern and a second dummy pattern corresponding to the first dummy pattern by etching at least a portion of the hardmask structure by using the first photoresist pattern and the first dummy pattern, forming a second photoresist layer on the second dummy pattern and the hardmask pattern, forming a second photoresist pattern covering the second dummy pattern and exposing the hardmask pattern, by exposing and developing the second photoresist layer, and forming a resulting pattern from the etch target layer by using the hardmask pattern as an etch mask, wherein, on a plane, one of the first area and the second area surrounds the other one of the first area and the second area.

According to another aspect of the inventive concepts, a method of forming patterns may include forming an etch target layer on a substrate, the substrate including a first area and a second area adjacent to the first area, forming a hardmask structure on the etch target layer, the hardmask structure including a plurality of hardmask layers, forming a first photoresist pattern and a first dummy pattern on the hardmask structure, according to a designed pattern of a designed layout, the first photoresist pattern and the first dummy pattern each comprising each including a metal oxide photoresist (MOR), forming a hardmask pattern and a second dummy pattern by etching at least one of the plurality of hardmask layers using the first photoresist pattern and the first dummy pattern as etch masks, and forming a resulting pattern from the etch target layer by using the hardmask pattern as an etch mask, wherein a pattern density of the designed pattern of the designed layout is greater than a pattern density of the resulting pattern on the substrate.

According to another aspect of the inventive concepts, a method of manufacturing an integrated circuit device may include forming an etch target layer on a substrate, the substrate including a memory cell area and a peripheral circuit area surrounding the memory cell area, forming a hardmask structure on the etch target layer in the memory cell area and the peripheral circuit area, forming a first photoresist layer on the hardmask structure in the memory cell area and the peripheral circuit area, the first photoresist layer including a metal material, forming a first dummy pattern in the memory cell area and forming a first photoresist pattern in the peripheral circuit area, by exposing and developing the first photoresist layer according to a designed layout, forming a second dummy pattern corresponding to the first dummy pattern in the memory cell area and forming a hardmask pattern corresponding to the first photoresist pattern in the peripheral circuit area, forming a second photoresist layer covering the hardmask pattern and the second dummy pattern in the memory cell area and the peripheral circuit area, forming a second photoresist pattern in the memory cell area by exposing and developing the second photoresist layer, and forming a resulting pattern from the etch target layer by using the hardmask pattern and the second photoresist pattern, wherein a pattern density of a designed pattern included in the designed layout and a pattern density of the resulting pattern on the substrate are different from each other.

### BRIEF DESCRIPTION OF THE DRAWINGS

Example embodiments will be more clearly understood from the following detailed description taken in conjunction with the accompanying drawings in which:

FIG. 1 is a layout diagram illustrating an integrated circuit device formed by a method of manufacturing an integrated circuit device, according to an example embodiment;

FIGS. 2 to 9 are cross-sectional views illustrating a method of forming patterns, according to an example embodiment;

FIG. 10 is a schematic plan view illustrating main components of a memory cell area illustrated in FIG. 1;

FIG. 11 is a plan view illustrating an example arrangement of a plurality of conductive patterns arranged in a peripheral circuit area illustrated in FIG. 1; and

FIGS. 12A to 15B are cross-sectional views illustrating a method of manufacturing an integrated circuit device, according to an example embodiment.

### DETAILED DESCRIPTION

Hereinafter, some example embodiments of the inventive concepts will be described in detail with reference to the accompanying drawings. Like reference numerals are used for like components in the drawings, and redundant descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

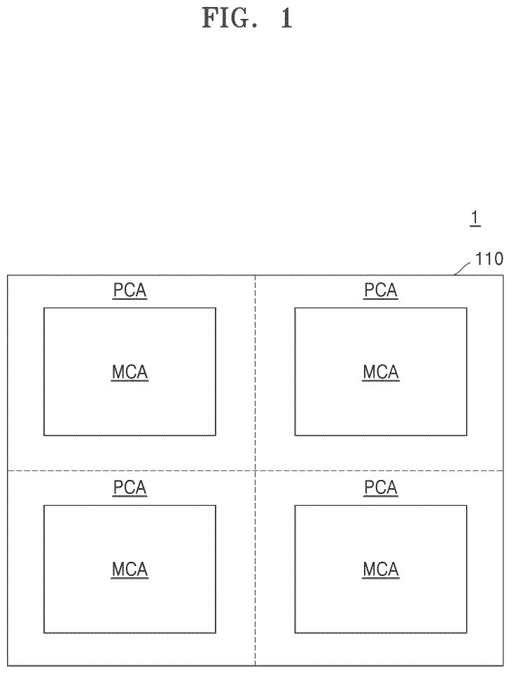

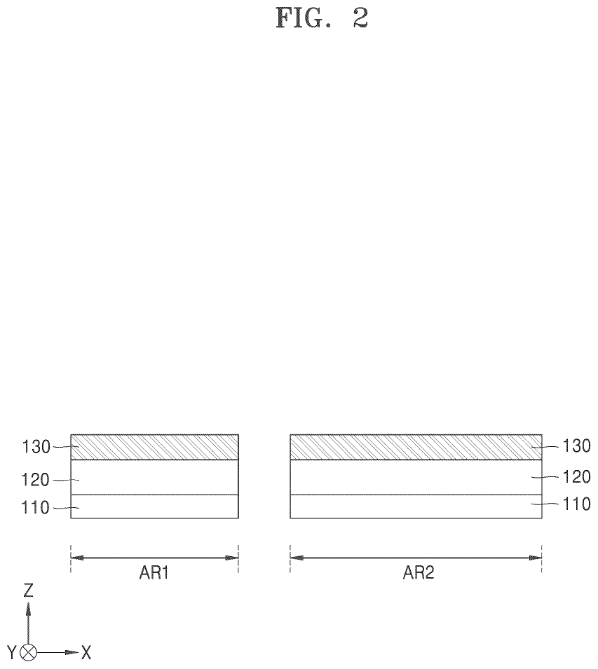

FIG. 1 is a layout diagram illustrating an integrated circuit device 1 formed by a method of manufacturing an integrated circuit device, according to an example embodiment.

Referring to FIG. 1, the integrated circuit device 1 may include a substrate 110 including a memory cell area MCA and a peripheral circuit area PCA. The peripheral circuit area PCA may surround the memory cell area MCA.

The memory cell area MCA may be an array area of volatile memory cells of a dynamic random-access memory (DRAM) device, and the peripheral circuit area PCA may be a core area or a peripheral circuit area of a DRAM device. For example, the peripheral circuit area PCA may include a peripheral circuit transistor for transmitting a signal and/or power to a memory cell array included in the memory cell area MCA.

In some example embodiments, the peripheral circuit transistor may constitute various circuits, such as a command decoder, a control logic, an address buffer, a row decoder, a column decoder, a sense amplifier, and a data input/output circuit.

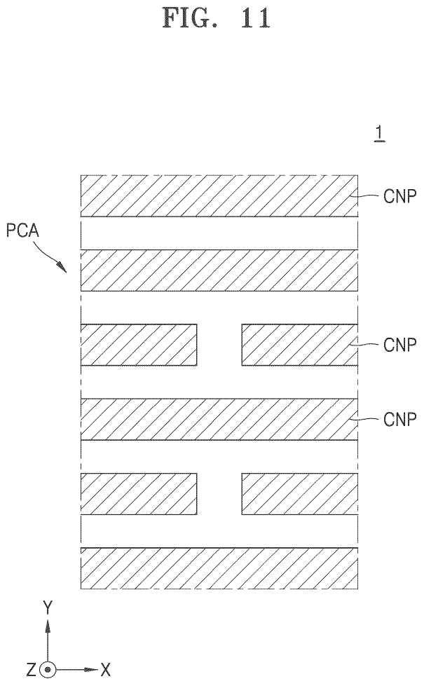

The memory cell area MCA and the peripheral circuit area PCA may have different pattern densities. In an example embodiment, in the memory cell area MCA, a plurality of patterns having relatively small widths may be separated from each other to form a regular arrangement and may be repeatedly formed at a relatively small pitch. In the peripheral circuit area PCA, a plurality of patterns having non-constant widths and lengths may be repeatedly formed at a non-constant pitch. Patterns formed in each of the memory cell area MCA and the peripheral circuit area PCA are described below with reference to FIGS. 10 and 11.

FIGS. 2 to 9 are cross-sectional views illustrating a method of forming patterns, according to an example embodiment. A first area AR1 and a second area AR2 may refer to different areas on the substrate 110, which do not overlap with each other. In FIGS. 2 to 9, the first area AR1 may refer to one of the memory cell area MCA and the peripheral circuit area PCA, and the second area AR2 may refer to the other one of the memory cell area MCA and the peripheral circuit area PCA.

Referring to FIG. 2, a lower structure 120 is formed on the substrate 110. An upper surface of the lower structure 120 may be at approximately the same or similar level in the first area AR1 and the second area AR2. Herein, the term “level” refers to a height extending in a vertical direction (a Z direction) from the upper surface of the substrate 110. An etch target layer 130 is formed on the lower structure 120.

The substrate 110 may include a semiconductor element, such as silicon (Si) or germanium (Ge), or a compound semiconductor, such as silicon carbide (SiC), gallium arsenide (GaAs), indium arsenide (InAs), or indium phosphide (InP). The lower structure 120 may include an insulating layer, a conductive layer, or a combination thereof. For example, the lower structure 120 may include structures including at least one conductive area. The conductive area may include a doped structure, a doped semiconductor layer, a metal layer, or a combination thereof. The lower structure 120 may include conductive areas, for example, wiring layers, contact plugs, transistors, etc., and insulating layers for insulating the conductive areas from each other. In an example embodiment, the etch target layer 130 may include an insulating pattern, a conductive pattern, or a combination thereof. In an example embodiment, the etch target layer 130 may include a doped semiconductor, metal, conductive metal nitride, or a combination thereof.

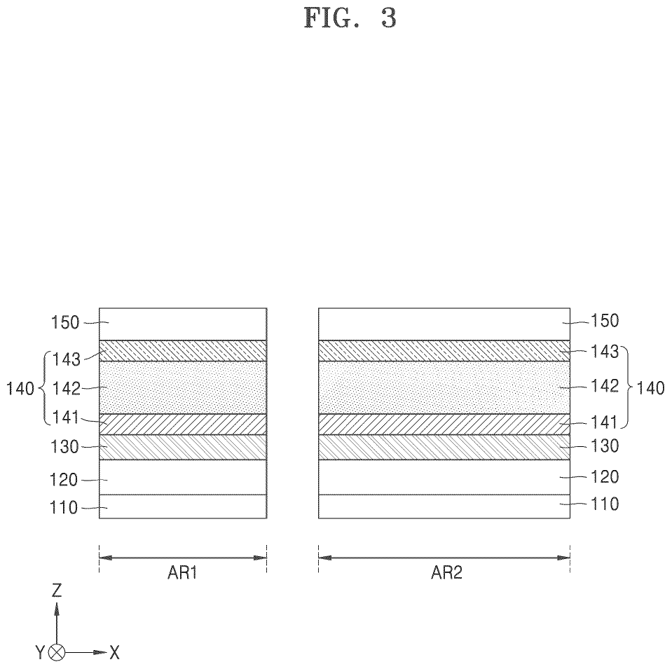

Referring to FIG. 3, a hardmask structure 140 including a plurality of hardmask layers is formed on the etch target layer 130, and a first photoresist layer 150 is formed on the hardmask structure 140. The first photoresist layer 150 may cover an upper surface of the hardmask structure 140.

The hardmask structure 140 may be arranged in the first area AR1 and the second area AR2. The hardmask structure 140 may include a first hardmask layer 141, a second hardmask layer 142, and a third hardmask layer 143, which are sequentially stacked on the etch target layer 130. The first hardmask layer 141, the second hardmask layer 142, and the third hardmask layer 143 may include different materials each having an etching selectivity different from those of other layers adjacent to each of the first hardmask layer 141, the second hardmask layer 142, and the third hardmask layer 143 at lower and upper portions thereof.

In an example embodiment, the first hardmask layer 141 may include a silicon oxide layer, a silicon nitride layer, or an amorphous carbon layer (ACL). The second hardmask layer 142 may include a spin-on hardmask (SOH) layer including a hydrocarbon compound or a derivative thereof, which has a relatively high carbon content of about 85 wt % to about 99 wt %. The third hardmask layer 143 may include silicon oxide, silicon nitride, silicon oxynitride, amorphous silicon, titanium, titanium dioxide, titanium nitride, chromium oxide, carbon, an organic anti-reflective coating (ARC) material, or a combination thereof.

The first photoresist layer 150 may include a resist for extreme ultraviolet (EUV) (13.5 nm), a resist for a krypton fluoride (KrF) excimer laser (248 nm), a resist for an argon fluoride (ArF) excimer laser (193 nm), and/or a resist for a fluorine (F₂) excimer laser (157 nm).

In an example embodiment, the first photoresist layer 150 may include a metal material and an inorganic material. For example, the first photoresist layer 150 may include a metal oxide photoresist (MOR). The first photoresist layer 150 may be formed by a deposition process and/or a spin coating process.

Hereinafter, for example, descriptions will be provided on the assumption that the first photoresist layer 150 includes a negative tone photoresist material. The first photoresist layer 150 may be arranged in the first area AR1 and the second area AR2. Accordingly, the upper surface of the hardmask structure 140 in each of the first area AR1 and the second area AR2 may not be exposed to the outside.

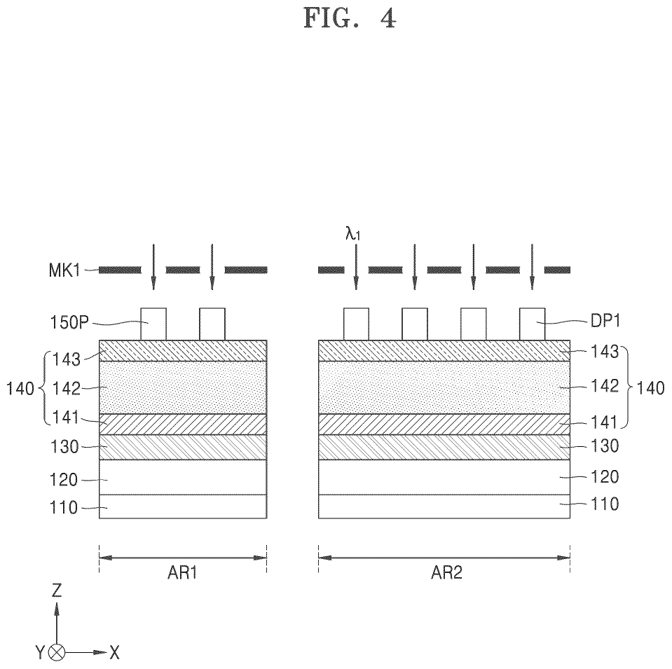

Referring to FIGS. 3 and 4, by exposing and developing the first photoresist layer 150, a first photoresist pattern 150P and a first dummy pattern DP1 may be formed from the first photoresist layer 150. In the exposing of the first photoresist layer 150, according to a designed layout, the first photoresist pattern 150P may be formed in the first area AR1, and the first dummy pattern DP1 may be formed in the second area AR2.

A designed pattern included in the designed layout may have the same (or similar) pattern density in the first area AR1 and the second area AR2. A pattern density of the first photoresist pattern 150P in the first area AR1 may be the same as (or similar to) a pattern density of the first dummy pattern DP1 in the second area AR2.

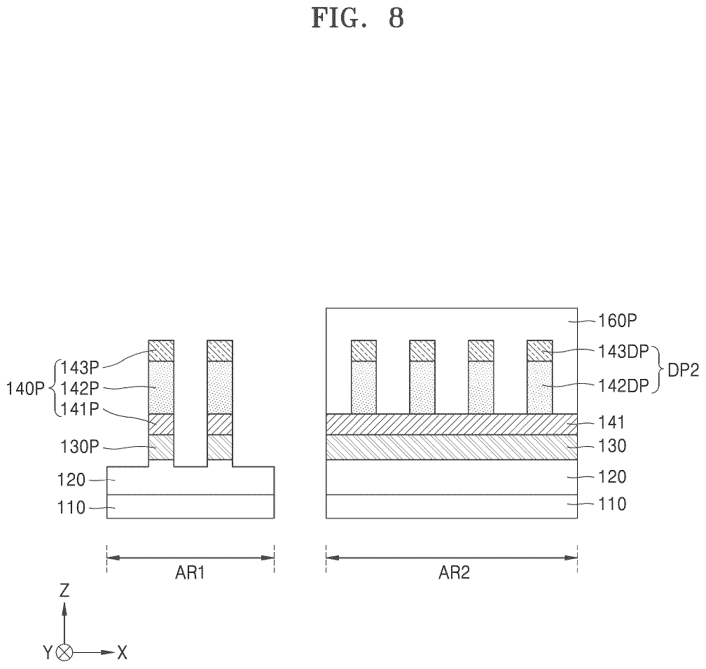

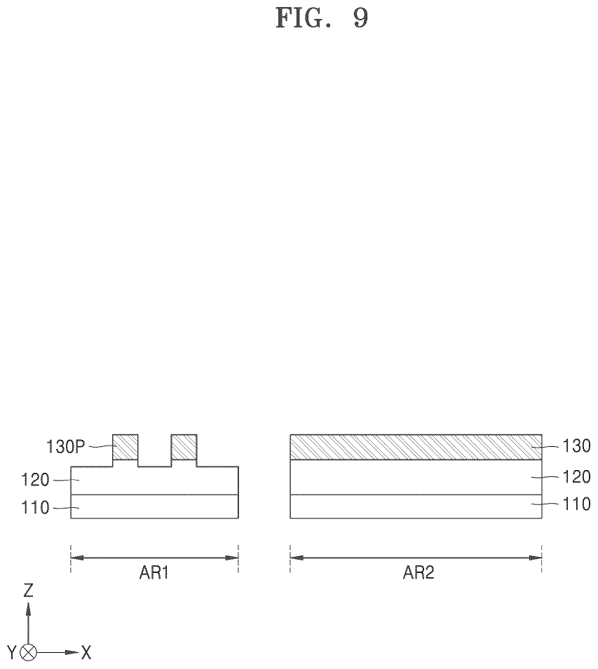

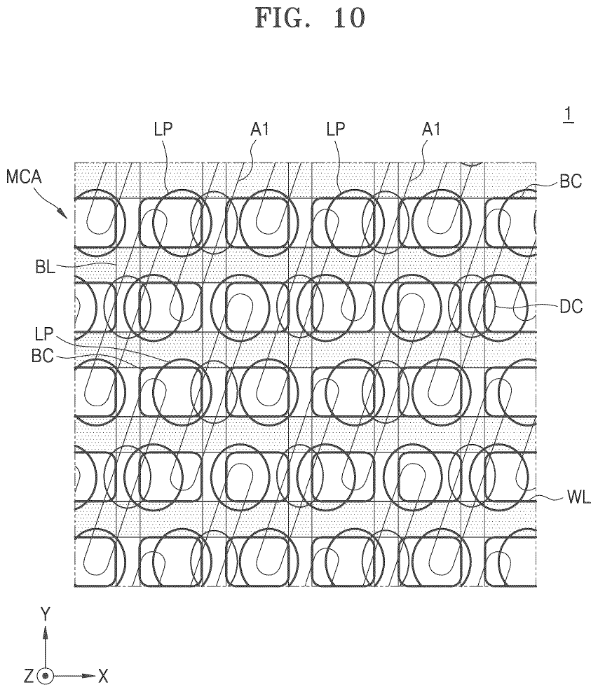

The first photoresist pattern 150P may be transferred to a resulting pattern according to the method of forming patterns, according to an example embodiment, and the first dummy pattern DP1 may not be transferred to the resulting pattern and may be deleted in the process of forming patterns. The first dummy pattern DP1 may be a component for making pattern densities of respective areas the same as (or similar to) each other when forming patterns by exposing the first photoresist layer 150. Detailed descriptions in this regard are provided below with reference to FIG. 8.

The first photoresist layer 150 may be exposed to light having a first wavelength λ₁, which has passed through a first mask MK1. For example, the first wavelength λ₁ may be 13.5 nm. That is, the light having the first wavelength λ¹ may be EUV. The first photoresist pattern 150P may be formed through an EUV lithography process.

The first mask MK1 may be open in at least a portion of the first area AR1 and at least a portion of the second area AR2. A mask being closed means that light incident on the mask does not pass through the mask, and a mask being open means that light incident on the mask passes through the mask.

Because the first photoresist layer 150 includes a negative tone photoresist material, a portion of the first photoresist layer 150 which is not exposed to light may be removed by a development process. Accordingly, the first photoresist pattern 150P may be formed in an area corresponding to an area in the first area AR1 in which the first mask MK1 is open, and the first dummy pattern DP1 may be formed in an area corresponding to an area in the second area AR2 in which the first mask MK1 is open.

By forming the first photoresist pattern 150P and the first dummy pattern DP1, at least a portion of the upper surface of the hardmask structure 140 in the first area AR1 and at least a portion of the upper surface of the hardmask structure 140 in the second area AR2 may be exposed. An exposure ratio of the upper surface of the hardmask structure 140 in the first area AR1 may be the same as (or similar to) an exposure ratio of the upper surface of the hardmask structure 140 in the second area AR2.

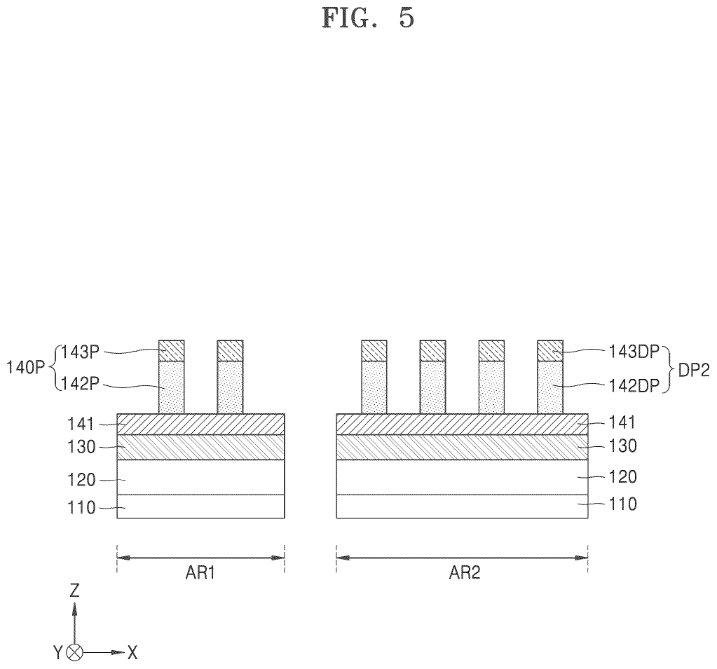

Referring to FIGS. 4 and 5, in the first area AR1, the first photoresist pattern 150P may function as an etch mask, and a hardmask pattern 140P to which the shape of the first photoresist pattern 150P is transferred may be formed. The hardmask pattern 140P may include a third hardmask pattern 143P and a second hardmask pattern 142P. In the process of forming the hardmask pattern 140P, the third hardmask layer 143 and the second hardmask layer 142 may be sequentially etched, and the third hardmask pattern 143P and the second hardmask pattern 142P, which correspond to the first photoresist pattern 150P, may be formed.

In the second area AR2, the first dummy pattern DP1 may function as an etch mask, and a second dummy pattern DP2 to which the shape of the first dummy pattern DP1 is transferred may be formed. The second dummy pattern DP2 may include a third hardmask dummy pattern 143DP and a second hardmask dummy pattern 142DP. In the process of forming the second dummy pattern DP2, the third hardmask layer 143 and the second hardmask layer 142 may be sequentially etched, and the third hardmask dummy pattern 143DP and the second hardmask dummy pattern 142DP, which correspond to the first dummy pattern DP1, may be formed. Regarding the patterns formed on the first hardmask layer 141, a pattern density in the first area AR1 and a pattern density in the second area AR2 may be the same as (or similar to) each other.

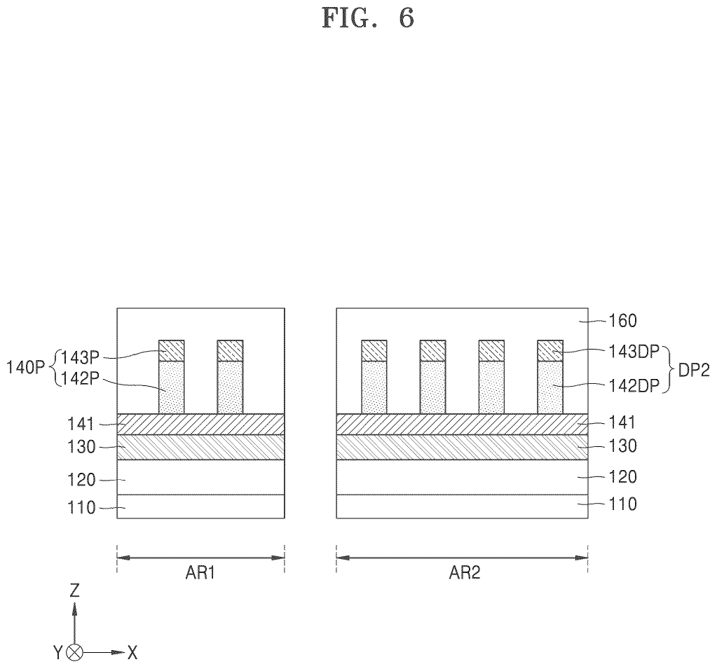

Referring to FIG. 6, a second photoresist layer 160 may be formed in the first area AR1 and the second area AR2. The second photoresist layer 160 may be formed on the hardmask pattern 140P and the second dummy pattern DP2. The second photoresist layer 160 may cover the hardmask pattern 140P in the first area AR1 and may cover the second dummy pattern DP2 in the second area AR2.

The second photoresist layer 160 may include a resist for EUV (13.5 nm), a resist for a KrF excimer laser (248 nm), a resist for an ArF excimer laser (193 nm), and/or a resist for an F₂ excimer laser (157 nm). The second photoresist layer 160 may include a metal material and an inorganic material. For example, the second photoresist layer 160 may include an MOR. The second photoresist layer 160 may be formed by a deposition process and/or a spin coating process.

Hereinafter, for example, descriptions will be provided on the assumption that the second photoresist layer 160 includes a negative tone photoresist material.

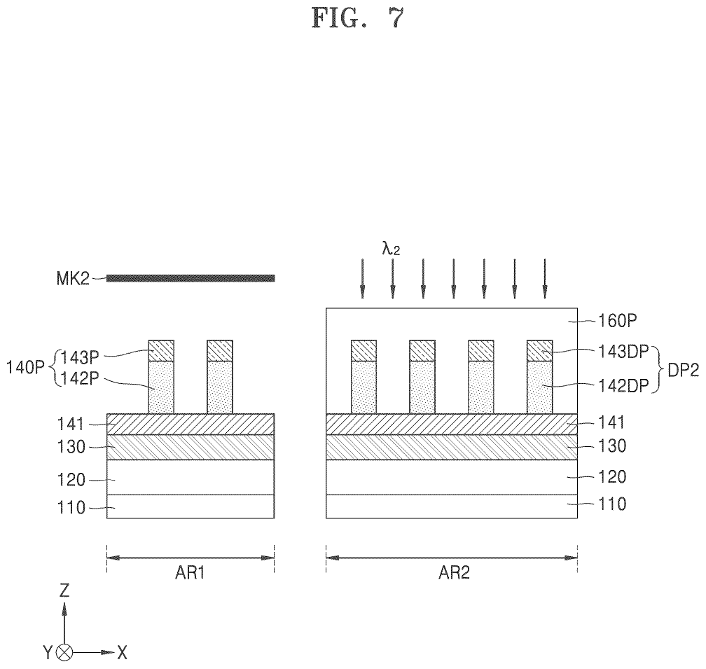

Referring to FIGS. 6 and 7, by exposing and developing the second photoresist layer 160, a second photoresist pattern 160P may be formed. The second photoresist layer 160 may be exposed to light having a second wavelength λ₂, which has passed through a second mask MK2. For example, the second wavelength λ₂ may be about 157 nm, about 193 nm, and/or about 248 nm. The second wavelength λ₂ may be longer than the first wavelength M. The second photoresist layer 160 may be exposed by a KrF excimer laser (248 nm), an ArF excimer laser (193 nm), or an F₂ excimer laser (157 nm). That is, in an example embodiment, the process of exposing the second photoresist layer 160 may be performed by using light having a different wavelength from light used in the process of exposing the first photoresist layer 150, considering process difficulty.

The second mask MK2 may be closed in the first area AR1 and may be open in the second area AR2. As described above, because the second photoresist layer 160 includes a negative tone photoresist material, a portion of the second photoresist layer 160 which is not exposed to light may be removed by a development process.

The second photoresist layer 160 may be removed in the first area AR1 corresponding to an area in which the second mask MK2 is closed, and the second photoresist layer 160 may form the second photoresist pattern 160P in the second area AR2 corresponding to an area in which the second mask MK2 is open. Accordingly, the second photoresist pattern 160P may cover the second dummy pattern DP2 and may expose the hardmask pattern 140P. The second photoresist pattern 160P may cover upper and side surfaces of the second dummy pattern DP2 in the second area AR2, and an upper surface of the third hardmask pattern 143P may be exposed in the first area AR1.

Referring to FIGS. 7 and 8, a resulting pattern 130P may be formed from the etch target layer 130 by using the hardmask pattern 140P as an etch mask.

In the first area AR1, by using the second hardmask pattern 142P and the third hardmask pattern 143P as etch masks, a first hardmask pattern 141P may be formed by removing a portion of the first hardmask layer 141, and the resulting pattern 130P may be formed by removing a portion of the etch target layer 130. In the process of forming the resulting pattern 130P, the first hardmask pattern 141P and the etch target layer 130 may be sequentially etched, and the resulting pattern 130P corresponding to the hardmask pattern 140P may be formed.

In the second area AR2, because the second photoresist pattern 160P is formed, the first hardmask layer 141 and the etch target layer 130 may not be removed. Because the second photoresist pattern 160P covers an upper surface of the second dummy pattern DP2 and an upper surface of the first hardmask layer 141, the etch target layer 130 may not be etched in the second area AR2.

Referring to FIGS. 8 and 9, the first hardmask pattern 141P, the second hardmask pattern 142P, and the third hardmask pattern 143P may be removed in the first area AR1, and the first hardmask layer 141, the second hardmask pattern 142P, the third hardmask pattern 143P, and the second photoresist pattern 160P may be removed in the second area AR2. Referring to FIG. 9, the resulting pattern 130P may be formed from the etch target layer 130 in the first area AR1, and an upper surface of the etch target layer 130 in the second area AR2 may be flat.

To summarize the descriptions provided with reference to FIGS. 2 to 9, in the method of forming patterns, according to an example embodiment, the etch target layer 130, the hardmask structure 140, and the first photoresist layer 150 may be formed on the substrate 110 on which the first area AR1 and the second area AR2 are defined. Afterwards, according to a designed layout, the first photoresist pattern 150P may be formed in the first area AR1, and the first dummy pattern DP1 may be formed in the second area AR2. The first photoresist pattern 150P may be transferred to the hardmask pattern 140P, which is subsequently used as an etch mask to form the resulting pattern 130P. The first dummy pattern DP1 may be transferred to the second dummy pattern DP2, but may not subsequently appear as the resulting pattern 130P.

The first dummy pattern DP1 may function to maintain a pattern density on the substrate 110 to be uniform in the exposing of the first photoresist layer 150. In particular, when the first photoresist layer 150 includes an MOR, due to component characteristics of the MOR, a critical dimension (CD) deviation of a pattern due to a pattern density difference may increase. In various example embodiments, in the exposing of the first photoresist layer 150, by forming the first dummy pattern DP1 in an area with a relatively low pattern density to compensate for the density, a CD deviation of a pattern may be reduced.

The method of forming patterns, according to an example embodiment, may include forming the second photoresist pattern 160P covering the second dummy pattern DP2 formed by the first dummy pattern DP1. The second photoresist pattern 160P may cover the second dummy pattern DP2 while exposing the hardmask pattern 140P. Accordingly, the first photoresist pattern 150P (or the hardmask pattern 140P) may be transferred to the resulting pattern 130P, and the first dummy pattern DP1 (or the second dummy pattern DP2) may not be transferred to the resulting pattern 130P.

That is, in the method of forming patterns, according to an example embodiment, to make a pattern density uniform in each area, in the exposing of the first photoresist layer 150, the first dummy pattern DP1 may be formed, but the first dummy pattern DP1, which is not a target pattern, may not be transferred to the resulting pattern 130P. That is, in the exposing of the first photoresist layer 150, a pattern density of a designed pattern included in the designed layout may be greater than a pattern density of the resulting pattern 130P.

According to the example embodiment described with reference to FIGS. 2 to 9, the first photoresist pattern 150P may be formed in the first area AR1, and the first dummy pattern DP1 may be formed in the second area AR2. To compensate for a pattern density with the first dummy pattern DP1, the designed pattern included in the designed layout may have the same (or similar) pattern density in the first area AR1 and the second area AR2. Afterwards, the first photoresist pattern 150P in the first area AR1 may be transferred to the resulting pattern 130P, and the first dummy pattern DP1 in the second area AR2 may not be transferred to the resulting pattern 130P, so that the resulting pattern 130P may have different pattern densities in the first area AR1 and the second area AR2. Accordingly, a pattern density difference between the first area AR1 and the second area AR2 in the designed pattern included in the designed layout may be less than a pattern density difference between the first area AR1 and the second area AR2 in the resulting pattern 130P.

In FIGS. 2 to 9, the first area AR1 may refer to one of the memory cell area MCA (see FIG. 1) and the peripheral circuit area PCA (see FIG. 1), and the second area AR2 may refer to the other one of the memory cell area MCA (see FIG. 1) and the peripheral circuit area PCA (see FIG. 1).

FIGS. 2 to 9 illustrate a method in which, when the first area AR1 is the memory cell area MCA (see FIG. 1) and the second area AR2 is the peripheral circuit area PCA (see FIG. 1), a dummy pattern is added to the peripheral circuit area PCA (see FIG. 1), and the resulting pattern 130P is formed in the memory cell area MCA (see FIG. 1). FIGS. 2 to 9 illustrate a method in which, when the first area AR1 is the peripheral circuit area PCA (see FIG. 1) and the second area AR2 is the memory cell area MCA (see FIG. 1), a dummy pattern is added to the memory cell area MCA (see FIG. 1), and the resulting pattern 130P is formed in the peripheral circuit area PCA (see FIG. 1).

In addition, FIGS. 2 to 9 illustrate an example in which the first area AR1 and the second area AR2 are one and the other one of the memory cell area MCA (see FIG. 1) and the peripheral circuit area PCA (see FIG. 1), respectively, but the inventive concepts are not limited thereto. The first area AR1 and the second area AR2 may refer to two different areas defined on the substrate 110 (see FIG. 1).

FIG. 10 is a schematic plan view illustrating main components of the memory cell area MCA illustrated in FIG. 1.

Referring to FIG. 10, the memory cell area MCA may include a plurality of cell active areas A1. Each of the plurality of cell active areas A1 may have a major axis in a diagonal direction with respect to a first horizontal direction (an X direction) and a second horizontal direction (a Y direction). A plurality of word lines WL may extend parallel to each other in the first horizontal direction (the X direction) across the plurality of cell active areas A1. A plurality of bit lines BL may extend parallel to each other in the second horizontal direction (the Y direction) on the plurality of word lines WL.

The plurality of bit lines BL may be connected to the plurality of cell active areas A1 via a direct contact DC. A plurality of buried contacts BC may be formed between two adjacent bit lines BL among the plurality of bit lines BL. The plurality of buried contacts BC may be arranged in a line in the first horizontal direction (the X direction) and the second horizontal direction (the Y direction). A plurality of conductive landing pads LP may be formed on the plurality of buried contacts BC. The plurality of buried contacts BC and the plurality of conductive landing pads LP may connect a lower electrode (not shown) of a capacitor formed above the plurality of bit lines BL to a cell active area A1. Each of the plurality of conductive landing pads LP may partially overlap a buried contact BC.

FIG. 11 is a plan view illustrating an example arrangement of a plurality of conductive patterns CNP arranged in the peripheral circuit area PCA illustrated in FIG. 1.

Referring to FIG. 11, the plurality of conductive patterns CNP may be arranged in the peripheral circuit area PCA of the integrated circuit device 1 illustrated in FIG. 1. Some of the plurality of conductive patterns CNP may extend parallel to each other. Some of the plurality of conductive patterns CNP may serve as conductive pads for connecting lower and upper conductive areas to each other. The plurality of conductive patterns CNP may be separated from each other with spaces of various sizes therebetween in a horizontal direction, for example, the first horizontal direction (the X direction) or the second horizontal direction (the Y direction). In some peripheral circuit areas PCA, a minimum separation distance between two adjacent conductive patterns CNP may be a minimum feature size of the integrated circuit device 1. In some other peripheral circuit areas PCA, a minimum separation distance between two adjacent conductive patterns CNP may be several to tens of times a minimum feature size of the integrated circuit device 1.

A horizontal width, for example, a width in the first horizontal direction (the X direction) and a width in the second horizontal direction (the Y direction), of each of the plurality of conductive patterns CNP and a horizontal separation distance, for example, a separation distance in the first horizontal direction (the X direction) and a separation distance in the second horizontal direction (the Y direction), between each pair of the plurality of conductive patterns CNP may vary.

The plurality of conductive landing pads LP and the direct contact DC illustrated in FIG. 10 and the plurality of conductive patterns CNP illustrated in FIG. 11 may be formed through a series of processes including a plurality of exposure processes. In some example embodiments, the series of processes for forming the plurality of conductive landing pads LP and the direct contact DC illustrated in FIG. 10 and the plurality of conductive patterns CNP illustrated in FIG. 11 may include one exposure process using an EUV light source and one exposure process using a KrF excimer laser (248 nm), ArF excimer laser (193 nm), and/or F₂ excimer laser (157 nm) light source. The exposure processes may include the method of forming patterns, described above with reference to FIGS. 2 to 9.

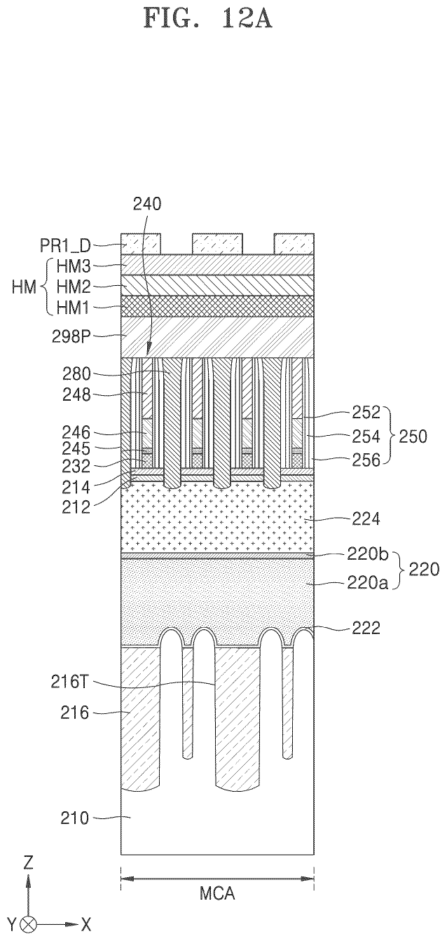

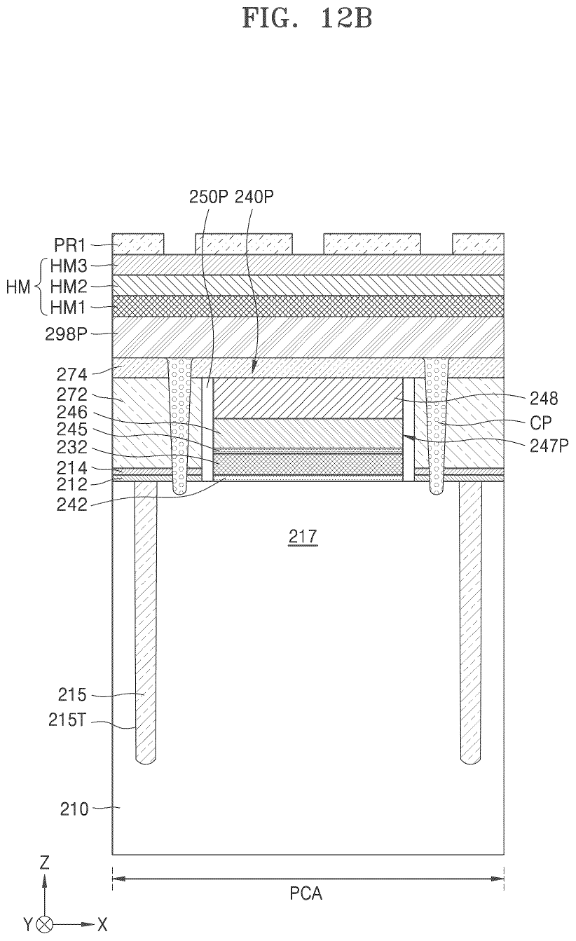

FIGS. 12A to 15B are cross-sectional views illustrating a method of manufacturing the integrated circuit device 1, according to an example embodiment. FIGS. 12A, 13A, 14A, and 15A are cross-sectional views of the memory cell area MCA, and FIGS. 12B, 13B, 14B, and 15B are cross-sectional views of the peripheral circuit area PCA. FIGS. 12A to 15B illustrate a process in which a pattern is formed only in the peripheral circuit area PCA. FIGS. 12A to 15B illustrate a wiring process of the integrated circuit device 1.

Referring to FIGS. 12A and 12B, in the memory cell area MCA and the peripheral circuit area PCA, a substrate 210, a first insulating layer pattern 212, a second insulating layer pattern 214, a peripheral device isolation layer 215, a device isolation layer 216, a word line 220, a buried insulating layer 224, a bit line structure 240, an insulating spacer 250, and an insulating fence 280 may be formed. The substrate 210 may correspond to the substrate 110 of FIG. 2.

First, in the memory cell area MCA, a device isolation layer trench 216T penetrating the substrate 210 may be formed, and the device isolation layer 216 may be formed inside the device isolation layer trench 216T. Thereafter, a gate dielectric layer 222, a lower word line 220a, and an upper word line 220b may be sequentially stacked on the substrate 210. The buried insulating layer 224, the first insulating layer pattern 212, and the second insulating layer pattern 214 may be sequentially stacked on the word line 220.

Thereafter, on the second insulating layer pattern 214, a conductive semiconductor pattern 232, a first metal-based conductive pattern 245, a second metal-based conductive pattern 246, and an insulating capping line 248 may be sequentially stacked, and first to third insulating spacers 252, 254, and 256 surrounding sidewalls of each of the conductive semiconductor pattern 232, the first metal-based conductive pattern 245, the second metal-based conductive pattern 246, and the insulating capping line 248 may be formed.

Thereafter, the insulating fence 280 penetrating at least a portion of each of the first insulating layer pattern 212, the second insulating layer pattern 214, and the buried insulating layer 224 may be formed adjacent to the insulating spacer 250. A preliminary insulating material layer 298P may be formed on the insulating fence 280. The preliminary insulating material layer 298P may correspond to the etch target layer 130 of FIG. 2.

In the peripheral circuit area PCA, a peripheral device isolation layer trench 215T penetrating at least a portion of the substrate 210 may be formed, and the peripheral device isolation layer 215 may be formed inside the peripheral device isolation layer trench 215T. Thereafter, the first insulating layer pattern 212 and the second insulating layer pattern 214 may be sequentially stacked on the substrate 210.

Thereafter, a gate line structure 240P may be formed on a peripheral active area 217. The gate line structure 240P may include a gate line 247P, an insulating capping line 248 covering the gate line 247P, and a gate insulating spacer 250P covering sidewalls of the gate line 247P and the insulating capping line 248. That is, the gate line 247P may have a stacked structure of the first metal-based conductive pattern 245 and the second metal-based conductive pattern 246. A gate insulating layer pattern 242 may be arranged between the gate line 247P and the peripheral active area 217. In some example embodiments, the gate line structure 240P may further include a conductive semiconductor pattern 232 arranged between the gate insulating layer pattern 242 and the first metal-based conductive pattern 245. A plurality of gate lines 247P may constitute the plurality of conductive patterns CNP illustrated in FIG. 11.

Thereafter, a first filling insulating layer 272 and a second filling insulating layer 274 may be formed on a sidewall of the gate line structure 240P. Thereafter, a contact plug CP may be formed to penetrate at least a portion of each of the substrate 210, the first insulating layer pattern 212, the second insulating layer pattern 214, the first filling insulating layer 272, and the second filling insulating layer 274. A preliminary insulating material layer 298P may be formed on the second filling insulating layer 274, and the preliminary insulating material layer 298P may correspond to the etch target layer 130 of FIG. 2.

A hardmask structure HM, which covers the entire upper surface of the preliminary insulating material layer 298P, and a first dummy pattern PR1_D may be formed on the preliminary insulating material layer 298P in the memory cell area MCA. In addition, a hardmask structure HM and a first photoresist pattern PR1 may be formed on the preliminary insulating material layer 298P in the peripheral circuit area PCA. The hardmask structure HM may include first to third hardmask layers HM1, HM2, and HM3.

The first dummy pattern PR1_D in the memory cell area MCA and the first photoresist pattern PR1 in the peripheral circuit area PCA may be formed by exposing and developing a first photoresist layer. The first photoresist layer may be exposed according to a designed layout. In an example embodiment, a designed pattern included in the designed layout may have the same (or similar) pattern density in the memory cell area MCA and the peripheral circuit area PCA. The first photoresist layer may include a metal material and an inorganic material. For example, the first photoresist layer may include an MOR.

When the first photoresist layer includes an MOR, in forming a pattern, a CD distribution of the pattern may increase due to a pattern density difference between areas. In the manufacturing method according to an example embodiment, by adding the first dummy pattern PR1_D in the process of exposing the first photoresist layer, the memory cell area MCA and the peripheral circuit area PCA may be formed to have a uniform pattern density.

At least a portion of an upper surface of the hardmask structure HM in the memory cell area MCA may be covered by the first dummy pattern PR1_D, and at least a portion of an upper surface of the hardmask structure HM in the peripheral circuit area PCA may be covered by the first photoresist pattern PR1.

In FIGS. 12A and 12B, the hardmask structure HM may correspond to the hardmask structure 140 of FIG. 4, the first photoresist pattern PR1 may correspond to the first photoresist pattern 150P of FIG. 4, and the first dummy pattern PR1_D may correspond to the first dummy pattern DP1 of FIG. 4.

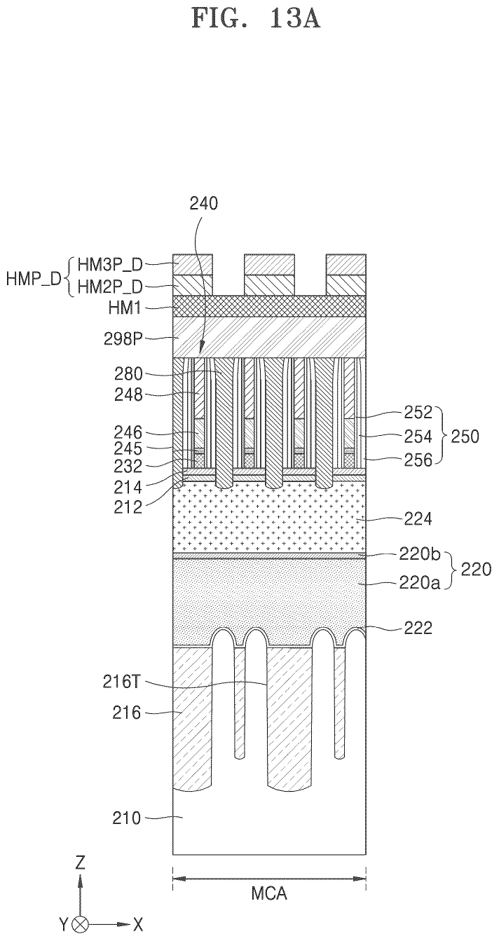

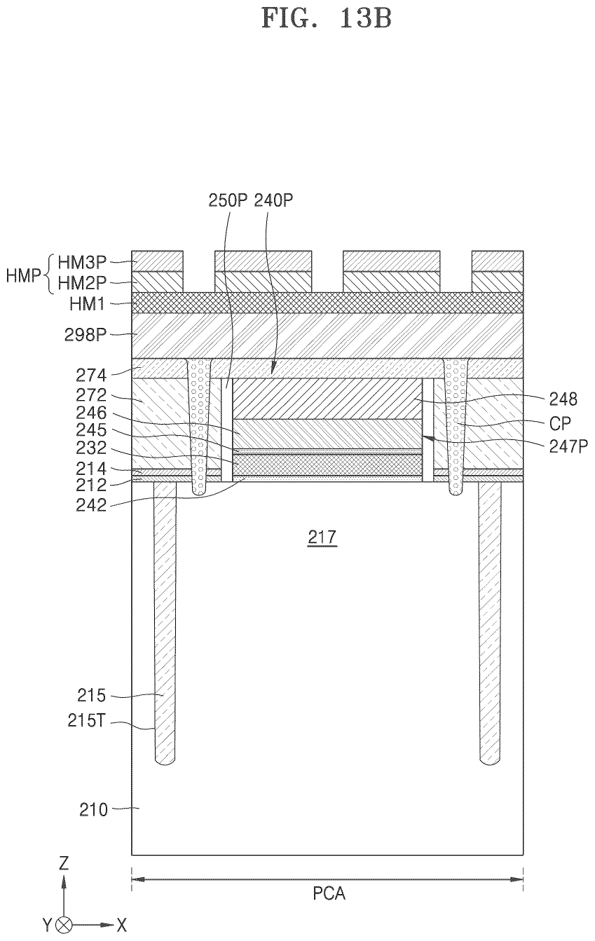

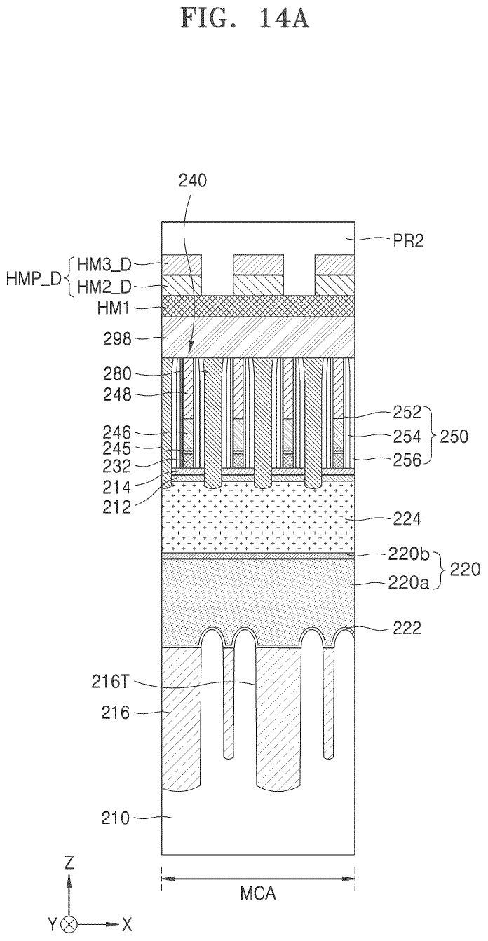

Referring to FIGS. 13A and 13B, in the memory cell area MCA, at least a portion of the hardmask structure HM may be etched by using the first dummy pattern PR1_D as an etch mask, and in the peripheral circuit area PCA, at least a portion of the hardmask structure HM may be etched by using the first photoresist pattern PR1 as an etch mask.

Accordingly, in the memory cell area MCA, a second dummy pattern HMP_D corresponding to the position of the first dummy pattern PR1_D may be formed. The second dummy pattern HMP_D may include a second hardmask dummy pattern HM2P_D and a third hardmask dummy pattern HM3P_D. In the peripheral circuit area PCA, a hardmask pattern HMP corresponding to the position of the first photoresist pattern PR1 may be formed. The hardmask pattern HMP may include a second hardmask pattern HM2P and a third hardmask pattern HM3P.

In FIGS. 13A and 13B, the second dummy pattern HMP_D may correspond to the second dummy pattern DP2 of FIG. 5, and the hardmask pattern HMP may correspond to the hardmask pattern 140P of FIG. 5.

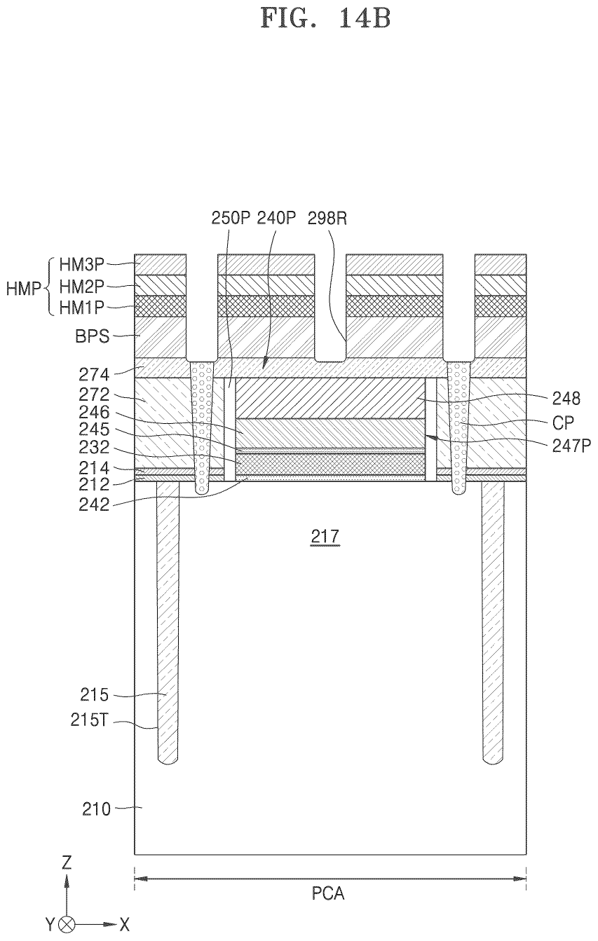

Referring to FIGS. 14A and 14B, in the memory cell area MCA, a second photoresist pattern PR2 covering the second dummy pattern HMP_D may be formed. The second photoresist pattern PR2 may be formed by forming a second photoresist layer in the memory cell area MCA and the peripheral circuit area PCA and then performing an exposure and development process thereon. The second photoresist layer may be removed in the peripheral circuit area PCA, and the second photoresist layer may form the second photoresist pattern PR2 in the memory cell area MCA. The second photoresist pattern PR2 may correspond to the second photoresist pattern 160P of FIG. 7.

After forming the second photoresist pattern PR2 (e.g., after covering the second dummy pattern HMP_D in the memory cell area MCA), the first hardmask layer HM1 and the preliminary insulating material layer 298P (see FIG. 13B) may be etched by using the hardmask pattern HMP as an etch mask. Accordingly, in the peripheral circuit area PCA, a plurality of peripheral bit line recesses 298R may be formed by removing portions of the preliminary insulating material layer 298P (see FIG. 13B). By forming the plurality of peripheral bit line recesses 298R in the preliminary insulating material layer 298P (see FIG. 13B), a peripheral bit line insulating structure BPS may be formed.

The peripheral bit line insulating structure BPS in which the plurality of peripheral bit line recesses 298R are formed may correspond to the resulting pattern 130P of FIG. 9.

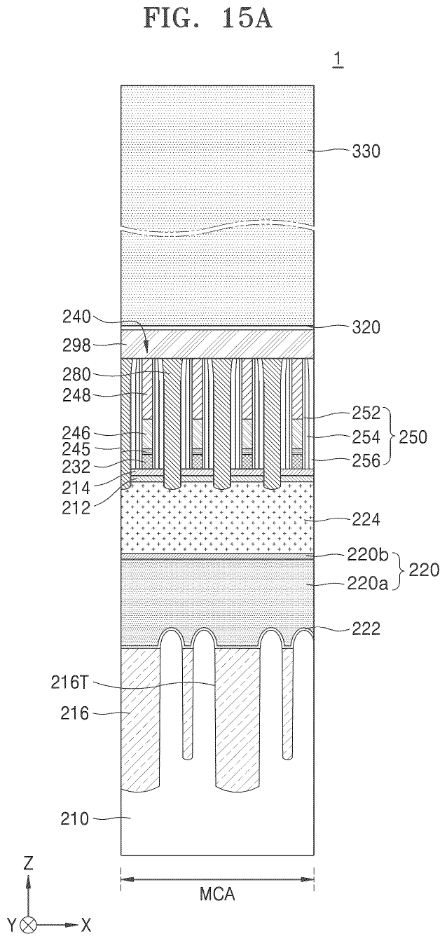

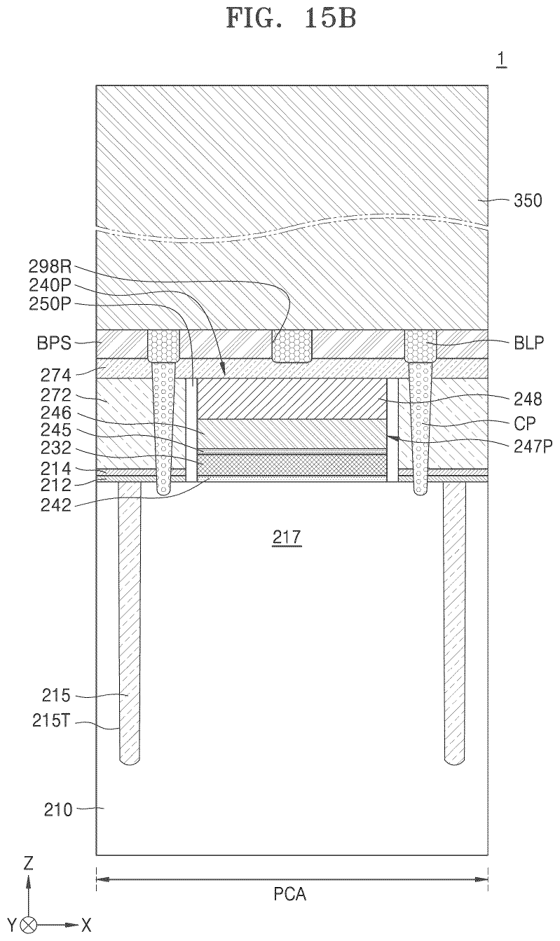

Referring to FIGS. 15A and 15B, in the memory cell area MCA, the second photoresist pattern PR2 and the second dummy pattern HMP_D may be removed. In an example embodiment, in the memory cell area MCA, at least a portion of the preliminary insulating material layer 298P (see FIG. 14A) may be removed to form an insulating material layer 298. In another example embodiment, the insulating material layer 298 may be formed without removing the preliminary insulating material layer 298P (see FIG. 14A). Thereafter, a capacitor dielectric layer 320 and an upper electrode 330 may be sequentially formed on the insulating material layer 298, thereby forming the integrated circuit device 1.

In the peripheral circuit area PCA, the hardmask pattern HMP may be removed, and a plurality of peripheral bit lines BLP may be formed in the plurality of peripheral bit line recesses 298R. Thereafter, a buried insulating layer 350 covering the plurality of peripheral bit lines BLP and the peripheral bit line insulating structure BPS may be formed, thereby forming the integrated circuit device 1.

Referring to FIGS. 12A and 15A, the first dummy pattern PR1_D is not transferred to the insulating material layer 298, and the first photoresist pattern PR1 is transferred to the peripheral bit line insulating structure BPS including the plurality of peripheral bit line recesses 298R. In the exposing of the first photoresist layer, the designed pattern included in the designed layout includes both the first dummy pattern PR1_D and the first photoresist pattern PR1. However, only a pattern corresponding to the first photoresist pattern PR1 may be formed as a resulting pattern in the preliminary insulating material layer 298P. That is, a pattern density of the designed pattern included in the designed layout may be greater than a pattern density of the resulting pattern.

FIGS. 12A to 15B illustrate a method of manufacturing an integrated circuit device, which includes a method of forming patterns wherein a pattern is not formed in the memory cell area MCA but only in the peripheral circuit area PCA, but example embodiments are not limited thereto. FIGS. 12A to 15B illustrate a method in which a dummy pattern is formed in the memory cell area MCA to compensate for a pattern density, and a pattern is formed in the peripheral circuit area PCA. However, in another example embodiment, a dummy pattern may be formed in the peripheral circuit area PCA to compensate for a pattern density, and a pattern may be formed in the memory cell area MCA.

While the inventive concepts have been particularly shown and described with reference to some example embodiments thereof, it will be understood that various changes in form and details may be made therein without departing from the spirit and scope of the following claims.

What is claimed is:

1. A method of forming patterns, the method comprising:
forming an etch target layer on a substrate, the substrate including a first area and a second area;
forming a hardmask structure on the etch target layer;
forming a first photoresist layer on the hardmask structure;
forming a first photoresist pattern and a first dummy pattern by exposing and developing the first photoresist layer;
forming a hardmask pattern corresponding to the first photoresist pattern and a second dummy pattern corresponding to the first dummy pattern by etching at least a portion of the hardmask structure by using the first photoresist pattern and the first dummy pattern;
forming a second photoresist layer on the second dummy pattern and the hardmask pattern;
forming a second photoresist pattern covering the second dummy pattern and exposing the hardmask pattern, by exposing and developing the second photoresist layer; and
forming a resulting pattern from the etch target layer by using the hardmask pattern as an etch mask,
wherein, in a plan view, one of the first area and the second area surrounds the other one of the first area and the second area.

2. The method of claim 1, wherein the forming of the first photoresist pattern and the first dummy pattern comprises forming the first photoresist pattern in the first area and forming the first dummy pattern in the second area.

3. The method of claim 2, wherein the forming of the second photoresist pattern comprises forming the second photoresist pattern over an entirety of the second area on an upper surface of the substrate.

4. The method of claim 2, wherein the forming of the first photoresist pattern and the first dummy pattern comprises exposing the first photoresist layer according to a designed layout,
wherein a designed pattern included in the designed layout has a same pattern density in the first area and the second area.

5. The method of claim 2, wherein, in the forming of the resulting pattern from the etch target layer, the resulting pattern has a greater pattern density in the first area than in the second area.

6. The method of claim 1, wherein a first wavelength of light for exposing the first photoresist layer is shorter than a second wavelength of light for exposing the second photoresist layer.

7. The method of claim 1, wherein the first photoresist pattern and the first dummy pattern each comprise a metal oxide photoresist (MOR).

8. The method of claim 1, wherein, in the forming of the resulting pattern from the etch target layer, the etch target layer remains in an area overlapping the second dummy pattern on the substrate and in an area overlapping an area between a pair of adjacent second dummy patterns.

9. The method of claim 1, wherein the first area is a memory cell area of an integrated circuit device, and the second area is a peripheral circuit area of the integrated circuit device.

10. A method of forming patterns, the method comprising:
forming an etch target layer on a substrate the substrate including a first area and a second area adjacent to the first area;
forming a hardmask structure on the etch target layer, the hardmask structure comprising a plurality of hardmask layers;
forming a first photoresist pattern and a first dummy pattern on the hardmask structure, according to a designed pattern of a designed layout, the first photoresist pattern and the first dummy pattern each comprising a metal oxide photoresist (MOR);
forming a hardmask pattern and a second dummy pattern by etching at least one of the plurality of hardmask layers using the first photoresist pattern and the first dummy pattern as etch masks; and
forming a resulting pattern from the etch target layer by using the hardmask pattern as an etch mask,
wherein a pattern density of the designed pattern of the designed layout is greater than a pattern density of the resulting pattern on the substrate.

11. The method of claim 10, wherein a pattern density difference between the first area and the second area in the designed pattern of the designed layout is less than a pattern density difference between the first area and the second area in the resulting pattern on the substrate.

12. The method of claim 10, wherein
the first dummy pattern is located in the second area, and
the second dummy pattern is formed by using the first dummy pattern as an etch mask in the second area.

13. The method of claim 11, wherein a pattern density of the resulting pattern in the first area is greater than a pattern density of the resulting pattern in the second area.

14. The method of claim 11, further comprising:
forming a second photoresist pattern covering an entirety of the second area in which the second dummy pattern is located on the substrate.

15. The method of claim 14, wherein
each of the first photoresist pattern and the second photoresist pattern is formed by applying a photoresist layer and then performing an exposure and development process thereon, and
the photoresist layer forming the first photoresist pattern comprises tin (Sn).

16. The method of claim 10, wherein, in the forming of the resulting pattern from the etch target layer, the etch target layer remains in an area overlapping the second dummy pattern on the substrate and in an area overlapping an area between a pair of adjacent second dummy patterns.

17. A method of manufacturing an integrated circuit device, the method comprising:
forming an etch target layer on a substrate, the substrate including a memory cell area and a peripheral circuit area surrounding the memory cell area;
forming a hardmask structure on the etch target layer in the memory cell area and the peripheral circuit area;
forming a first photoresist layer on the hardmask structure in the memory cell area and the peripheral circuit area, the first photoresist layer comprising a metal material;
forming a first dummy pattern in the memory cell area and forming a first photoresist pattern in the peripheral circuit area, by exposing and developing the first photoresist layer according to a designed layout;
forming a second dummy pattern corresponding to the first dummy pattern in the memory cell area and forming a hardmask pattern corresponding to the first photoresist pattern in the peripheral circuit area;
forming a second photoresist layer covering the hardmask pattern and the second dummy pattern in the memory cell area and the peripheral circuit area;
forming a second photoresist pattern in the memory cell area by exposing and developing the second photoresist layer; and
forming a resulting pattern from the etch target layer by using the hardmask pattern and the second photoresist pattern,
wherein a pattern density of a designed pattern included in the designed layout and a pattern density of the resulting pattern on the substrate are different from each other.

18. The method of claim 17, wherein
the first photoresist pattern is formed by an exposure process using an extreme ultraviolet (EUV) light source, and
the second photoresist pattern is formed by an exposure process using one of a krypton fluoride (KrF) light source and an argon fluoride (ArF) light source.

19. The method of claim 17, wherein the first photoresist pattern comprises a metal oxide photoresist (MOR).

20. The method of claim 17, wherein a pattern density difference between the memory cell area and the peripheral circuit area in the designed pattern of the designed layout is less than a pattern density difference between the memory cell area and the peripheral circuit area in the resulting pattern on the substrate.
